(19) United States
(12) Patent Application Publication
(10) Pub. No.: US 2011/0101997 A1
(43) Pub. Date: May 5, 2011

(54) Flush-Mounted Capacitive Sensor Mount

(75) Inventor: Joel Gulbranson, Ham Lake, MN (US)

(73) Assignee: AGRICHEM, INC., Ham Lake, MN (US)

(21) Appl. No.: 12/980,949

(22) Filed: Dec. 29, 2010

Related U.S. Application Data
(63) Continuation-in-part of application No. 12/044,086, filed on Mar. 7, 2008, now abandoned.

(51) Int. Cl. G01R 27/26; G01N 9/36

(52) U.S. Cl. 324/664; 324/663

(57) ABSTRACT

In some embodiments, a method of monitoring particulates may include one or more of the following steps: (a) receiving the particulates in a particulate flow channel mounted within a chute or conduit, (b) collecting a particulate sample in a body section of the flow channel, (c) sensing moisture content of the particulate with a flush mounted capacitive sensor, (d) allowing the particulate to empty out of the flow channel through an opening in a discharge section of the flow channel, (e) concentrating the particulate sample at a sensor surface, and (f) shielding the sensor from stray electromagnetic fields.

### CROSS-REFERENCE TO RELATED APPLICATION

The present application is a Continuation-in-Part of U.S. patent application Ser. No. 12/044,086, filed on Mar. 7, 2008, herein incorporated by reference in its entirety.

### BACKGROUND OF THE INVENTION

I. Field of the Invention

Embodiments of the present invention generally relate to sensors. Particularly, embodiments of the present invention relate to capacitive sensors. More particularly, embodiments of the present invention relate to capacitive sensors for measuring dielectric properties such as moisture, density and/or detecting the presence or proximity of an object.

II. Background

Moisture monitoring and control are extremely important in processing many particulate materials ranging from feed grain to coal to kitty litter. Too much moisture can create problems with spoilage and flow characteristics. Too little moisture frequently results in dusty conditions in the processing area. If the low moisture content is caused by over-drying during processing, energy has been wasted to produce an inferior, dusty product. If the product is a food or feed material, over-drying can damage flavor, aroma, and nutrient availability.

Moisture in percentage amounts is monitored as a specification in commercial food and feed production.

The standard reference laboratory method for measuring moisture content in solid or semi-solid materials is loss on drying (LOD). In this technique a sample of material is taken from the process, weighed, heated in an oven for a specified period, cooled in the dry atmosphere of a desiccator, and then reweighed. If the volatile content of the solid is primarily water, the LOD technique gives a good measure of moisture content. Because the manual laboratory method generally requires up to 72 hours, automated moisture analyzers have been developed to reduce the time necessary for an assay to just a few minutes. Even these devices require a sample to be removed from a particulate process stream for the moisture assay, are labor intensive and are of limited use for on-line moisture monitoring and process control systems required for optimum energy use and finished product quality.

The sensor contains no moving parts, is rugged, simple to use, easy to clean, and can be designed for high temperature and pressure applications. Appropriate choice of sensor components reduces or eliminates problems caused by abrasion and corrosion.

Most capacitive sensors for measuring material properties use a parallel plate or concentric cylinder design. The sensors work well in the laboratory or in a continuous stream of material, but certain applications require a less obtrusive sensor such as monitoring particulate, meal or powder moisture content in a mixer or screw conveyor. The flush mounted design can operate in these mechanically hostile environments.

Capacitive moisture sensors have been shown to be rugged, reliable, and economical as laboratory or desk-top instruments and are widely used in the grain industry. Since their signals are affected by moisture content, density, and temperature of the particulate sample, controlling sample density and accurately measuring temperature are essential for an accurate moisture assay. Controlling density of a flowing particulate material in an on-line industrial setting has been a very difficult problem not previously solved.

It would be desirable for a capacitive on-line process sensor to also be rugged, reliable, and economical. Further, it would be desirable for such a capacitive sensor to control-sample density and accurately measure temperature.

### SUMMARY OF THE INVENTION

In some embodiments, a sensor mount may include one or more of the following features: (a) a receiver section coupled to a body section, (b) a discharge section coupled to the body section, (c) a capacitive sensor coupled to the body section, (d) a flared opening on the receiver section, and (e) a reduced opening on the discharge section.

In some embodiments, a method of manufacturing a sensor mount may include one or more of the following steps: (a) forming integrally a receiver section, a body section, and a discharge section, (b) coupling a capacitive sensor to the body section, (c) forming a flare in the receiver section for receiving particulate, (d) forming mounting holes in the body section for coupling the capacitive sensor to the body section with fasteners, and (e) forming the capacitive sensor from a dielectric substrate having a planar configuration with a pair of sensing electrodes arranged on one surface of said substrate in spaced relation, and a shielding electrode being grounded and arranged between and parallel to said pair of sensing electrodes.

In some embodiments, a method of monitoring particulates may include one or more of the following steps: (a) receiving the particulates in a sensor mount, (b) collecting a particulate sample in a body section of the sensor mount, (c) sensing moisture content of the particulate with a flush mounted capacitive sensor, (d) allowing the particulate to empty out of the sensor mount through a narrowed opening in a discharge section of the sensor mount, (e) concentrating the particulate sample at a sensor surface, (f) shielding the sensor from stray electric fields, and (g) inputting the particulate at the funnel opening of the sensor mount.

### DESCRIPTION OF THE DRAWINGS

FIG. 1 shows a side view of a flush-mounted capacitive sensor mount in an embodiment of the present invention;

FIG. 1B shows a front view of a flush-mounted capacitive sensor mount in an embodiment of the present invention;

FIG. 2 is a front plan view of a capacitive sensor element according to an embodiment of the invention;

FIG. 3 is a sectional view of a sensor element taken along line 2-2 of FIG. 4;

FIG. 4 is a side plan view of a sensor element representing an electric field generated by sensing electrodes in an embodiment of the present invention;

FIG. 5 is an elevated side profile of a flush-mounted capacitive sensor mount in an embodiment of the present invention;

FIG. 6 is a flow process diagram of a method of sensing moisture in flowing particulate in an embodiment of the present invention; and

FIG. 7 is an isometric view of an alternative embodiment of the invention.

### DESCRIPTION OF THE PREFERRED EMBODIMENT

The following discussion is presented to enable a person skilled in the art to make and use the present teachings. Various modifications to the illustrated embodiments will be readily apparent to those skilled in the art, and the generic principles herein may be applied to other embodiments and applications without departing from the present teachings. Thus, the present teachings are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of the present teachings. Skilled artisans will recognize the examples provided herein have many useful alternatives and fall within the scope of the present teachings. While embodiments of the invention discussed below are discussed in detail with respect to moisture detection and control in crops such as grains, soybeans, etc., it is fully contemplated embodiments of this invention could be extended to moisture detection and control for most any particulate, aggregate, or any material requiring moisture monitoring without departing from the spirit of the invention.

Drying is a mass transfer process resulting in the removal of water by evaporation from a solid or semi-solid. Hundreds of millions of tons of wheat, corn, soybean, rice, sorghum, sunflower seeds, rapeseed/canola, barley, oats, etc., are dried each year. Drying typically reduces moisture content from 17-30% (by weight) to values between 8 and 15% w/w, depending on the grain and its end use.

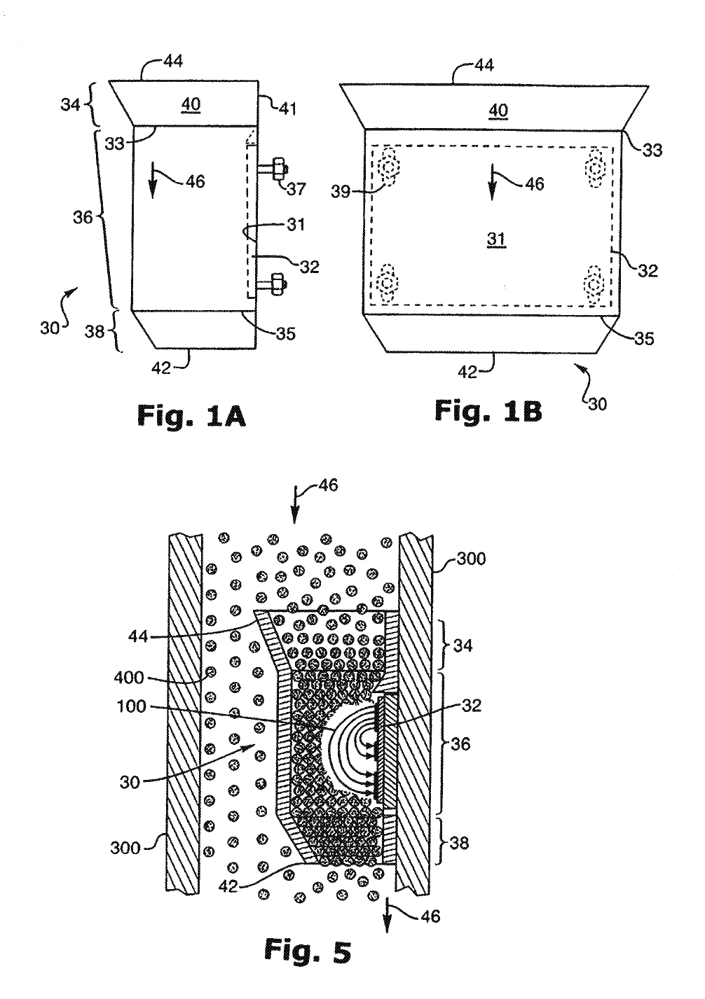

With reference to FIGS. 1A and 1B, views of a flush-mounted capacitive sensor mount in a first embodiment of the present invention are shown. A defined area sensor mount (DASM) 30 can be designed to collect and concentrate flowing particulate materials. It is understood for the discussion of this invention, particulate can be most any material such as sand, coal, grain, kitty litter, or silicon 22 without limitation to these examples given and without departing from the spirit of the invention. This can provide a constant reproducible physical and electric field environment for a flush-mounted capacitive sensor 32, as will be described in more detail below.

DASM 30 can be designed to be mounted in a location such as a chute, downspout, or at the discharge from conveyances such as belt, bucket, or screw conveyors where particulate materials are flowing by gravity and subject to having variable volumes and densities. DASM 30 continuously collects a proportional sample from the particulate flow, concentrates it at a sensor surface 31 and provides a reproducible sample volume and density.

DASM 30 can also shield sensor 32 from stray electromagnetic fields possibly present in particulate processing facility 10 and possibly isolate sensor 32 from potential grounding effects of nearby equipment or structures.

DASM 30 can have three body sections: A receiver section 34, a body section 36, and a discharge section 38. Overall, DASM can be 10.37 inches in height by 10.90 inches in width. Receiver section 34 has an opening 40 located at body section end 33 with a flare 44 having a width reducing from 10.90 inches to 7.90 inches to funnel particulate into body section 36. Receiving section flare 44, having flat backside 41, funnels particulate into body section 36 to keep body section 36 filled with particulate, thus assisting in concentrating the particulate into a central location, body section 36, to be monitored. Discharge section 38 has an opening 42 located at body section end 35 with a width reducing from 7.90 inches to 5.74 inches. This width reduction provides flow restriction at discharge section 38 to provide a consistent, reproducible, particulate density in body section 36 by restricting flow of particulate out of opening 42 causing particulate to back up and fill body section 36. DASM 30 can be integrally formed of any material such as a plastic, fiberglass or metal. However, it is helpful if DASM 30 is formed of a conductive composite material or metal to assist in electrically isolating sensor 32 from stray electromagnetic fields that may be present in the surrounding area.

Sensor 32 may have a surface area of about 4.675 inches by 7.675 inches mounted with a long dimension perpendicular to a particulate flow direction shown by arrow 46. In an alternative embodiment, sensor 32 could be mounted with the long dimension parallel to the particulate flow direction 46. It is noted the shape of DASM 30 and orientation of sensor 32 can be dictated by the space available where DASM 30 would be installed. It is further contemplated DASM 30 and sensor 32 could have most any dimension without departing from the spirit of the invention. All DASM 30 dimensions could be altered to physically fit a particular site and or particulate material having any unique physical and or chemical properties. One embodiment could include an adjustable gate at discharge section 38.

Sensor 32 is described with reference to FIGS. 2-4 is similar to that described in the Greer U.S. Pat. No. 6,249,130, owned by applicant's assignee and that is incorporated by reference herein. Sensor 32 includes a substrate 104 formed of printed circuit board material and having a planar configuration. On one surface of substrate 104 is provided a spaced pair of sensing electrodes 60. Electrodes 60 are coplanar and can have a rectangular configuration. However, it will be appreciated by those of ordinary skill in the art that other configurations (e.g., concentric rings) may be used for sensing electrodes 60 so long as they are spaced from one another. Sensing electrodes 60 are formed of a conductive material. Electrodes 60 can be formed of a copper film in a printed circuit fabrication process.

When alternating power is applied to the sensing electrodes 60A and 60B from a power supply 80, an electric field represented by lines 100 is generated between electrode 60A and electrode 60B. Collectively, lines 100 represent an electric field for sensing elements 60 as will be developed in greater detail below.

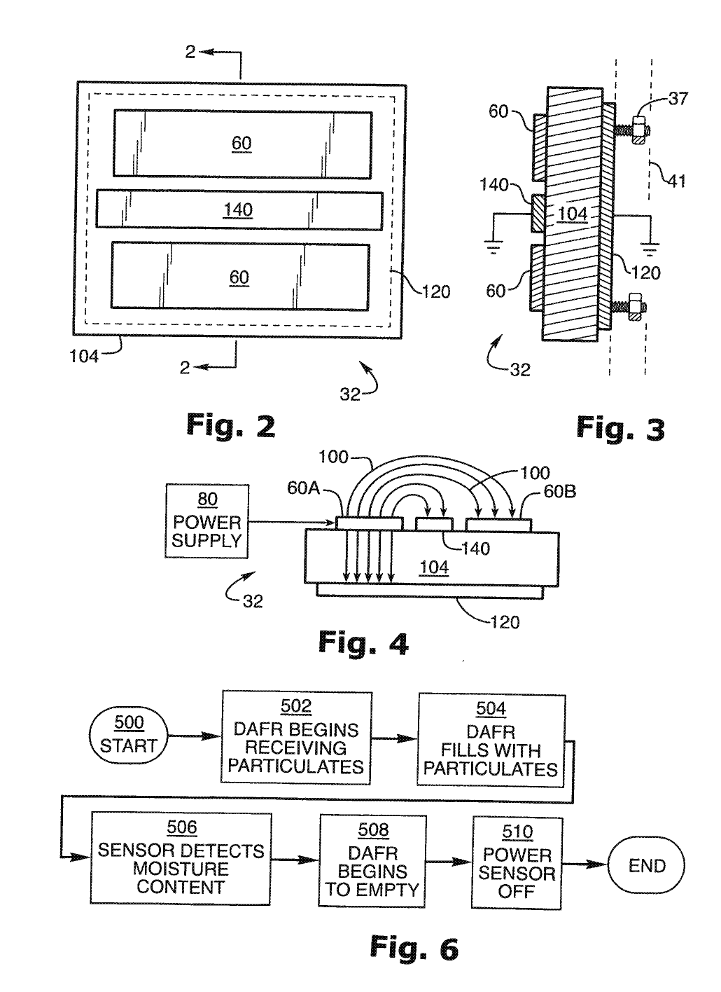

Two shield electrodes are also mounted on substrate 104, both shield electrodes being connected with a reference potential, e.g. ground. First shield electrode 120 is arranged on the surface of substrate 104 opposite the surface on which sensing electrodes 60 are arranged. First shield electrode 120 has a configuration similar to but less than substrate 104 and is arranged parallel to sensing electrodes 60. Referring to FIG. 4, first shield electrode 120 intercepts or blocks electric field 100 from extending to the rear or opposite surface of sensing electrodes 60. Thus, sensor 32 only measures or detects objects within the 180° field on the sensing electrode side of the element. Interference from behind the element, e.g., the side on which first shield element 120 is arranged, is prevented.

A second shield electrode 140 is arranged on the front surface of dielectric substrate 104 between and co-planar with sensing electrodes 60 in spaced parallel relation. Second shield electrode 140 intercepts or blocks electric field 100 closest to the sensing element. This prevents the densest portion of electric field 100 very near the element from severely dominating capacitive measurements.

If desired, a protective dielectric layer, such as a ceramic coating, can be provided over sensing electrodes 60, second shield electrode 140, and the remainder of the one surface of dielectric substrate 104. Such a coating serves to protect the sensor from abrasive wear due to the particulate material flowing over its surface.

The useful electric field 100 originates in sensing electrode 60A and terminates in sensing electrode 60B. This electric field 100 extends outwardly into the object or material being sensed. As an object enters the useful electric field 100, the change in capacitance between the sensing electrodes 60 is detected (for proximity detectors) or measured (for content measuring devices). More particularly, the dielectric properties of a material or object intercepting the electric field are detected and measured as a capacitance change. This is particularly useful for measuring properties such as moisture content, density or composition of a particulate solid. The shape and size of sensing electrodes 60 and shield electrodes 120 and 140 will determine the sensing range of the capacitive sensing element 32 according to embodiments of the invention. Larger sensing electrodes 60 spaced farther apart and wide coplanar shield electrodes 120 and 140 will provide more distant sensing, while smaller and more closely spaced electrodes will provide measurements closer to the element.

With reference to FIGS. 5 and 6, a method of sensing a parameter, such as moisture, in flowing particulate 400 in an embodiment of the present invention is shown. During operation of process 500, particulate 400 begins to flow into DASM 30 a flared, funnel-like opening 44 of receiving section 34 at state 502. It is noted, DASM 30 is flush mounted to chute 300. DASM 30 is designed to collect and concentrate flowing particulate materials 400 to subject particulate 400 to a constant reproducible physical and electric field 100. DASM 30 can be mounted to a chute 300 to receive particulate 400 flowing by gravity through the chute. DASM 30 could also be mounted to the discharge end of a belt, bucket, or screw conveyor to receive direct discharge (or flow through) of particulate 400.

Some particulate 400 will flow out through discharge end 38; however, due to discharge end 38 tapering to a more narrow opening 42 than the funnel-like entrance, particulate 400 entering DASM 30 will buildup to a relatively constant volume of material in front of the sensor 32. Particulate 400 can be most any particulate, such as corn, kitty litter, or pulverized coal, and can be received by DASM 30 by a mode, such as chute 300 shown in FIG. 5. Therefore, DASM 30 will tend to fill with particulate 400 at state 504. DASM 30 continuously collects a proportional sample from particulate flow through the chute 300, concentrates it in a body 36 directly in front of sensor 32, thus providing a constantly moving, but consistent sample volume and density for sensing by the sensor 32. Sensor 32 held in place by fasteners 37 at mounting holes 39, can now begin the process of detecting the composition or density of a particulate 400 and/or detecting moisture content of particulate 400 at state 506, based upon changes in capacitance resulting from variations in the dielectric constant of the material due to a shift in the particulate's composition, density or moisture changes.

DASM 30 shields sensor 32 from stray electromagnetic fields 100 present in the particulate processing facility. This is due to DASM's 30 metal construction which absorbs stray electromagnetic fields 100 present and routes these signals to ground; however, as discussed above, DASM 30 can be constructed from most any type of conductive material. The operational amplifier circuit shown in FIG. 4 of the aforereferenced Greer '130 patent may be used to provide an output that varies proportionally with sensor 32 capacitance.

After all particulate 400 has stopped entering the chute 300 and, hence, the DASM 30, DASM 30 begins to empty at state 508. At state 510, sensor 32 can be powered off and moisture detection process 500 can be complete.

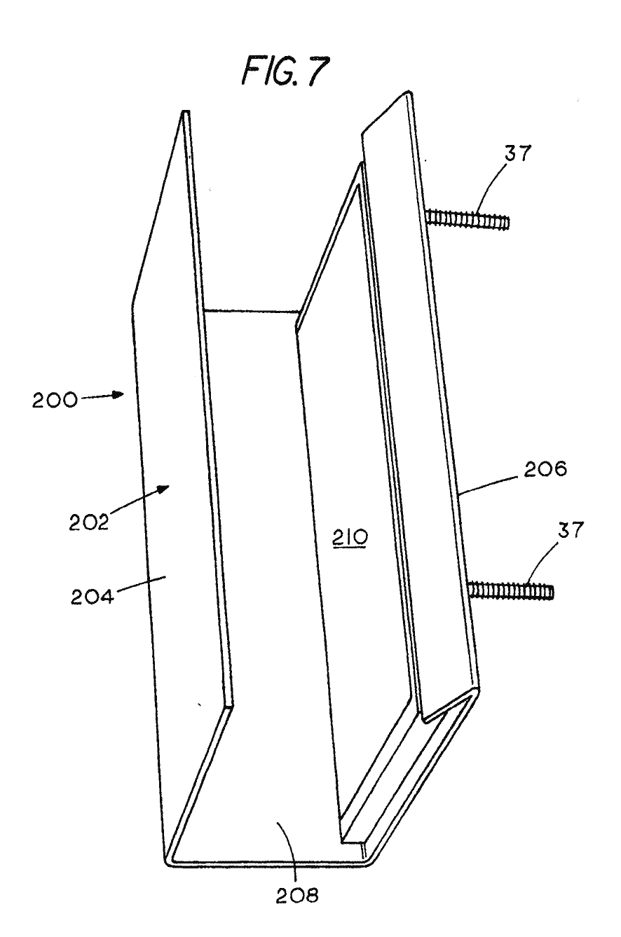

FIG. 7 shows an alternative embodiment of the present invention specifically designed for use in a column of grain flowing downward by gravity and having a consistent density. As shown in FIG. 7, the capacitive sensor mount is indicated generally by numeral 200 and is seen to comprise a generally U-shaped channel 202 having a pair of parallel sidewalls 204 and 206 joined together by an end wall 208. The sensor of FIG. 5 is shown as being affixed to the sidewall 206 by the bolts 37 that extend through holes drilled in the sidewall 206 and the bolts 37 are made sufficiently long to also pass through a wall of the grain chute or downspout (not shown) for attachment thereto in the path of the flowing particulate material.

In FIG. 7, the electrodes 60 and 140, as well as the face of the substrate 104 on which those electrodes are mounted, are coated by a suitable ceramic material 210 which is highly resistant to wear due to abrasion. A suitable electrical harness (not shown) also extends through the sidewall 206 and is electrically joined to the electrodes 60, 120 and 140 as shown in FIG. 5, to apply an alternating current across the electrodes and thereby produce an electric field within the channel 202. Thus, embodiments of the FLUSH-MOUNTED CAPACITIVE SENSOR MOUNT are disclosed. One skilled in the art will appreciate the present teachings can be practiced with embodiments other than those disclosed. The disclosed embodiments are presented for purposes of illustration and not limitation, and the present teachings are limited only by the claims follow.

1. A monitoring apparatus for particulate material flowing downward by gravity in a column comprising:
(a) a sampling chamber adapted to be disposed in a column of particulate material, the sampling chamber comprising a channel of generally U-shaped cross-section with a pair of opposed side walls joined by an end wall;
(b) a generally flat capacitive sensing element affixed to one of the side walls and adapted to be immersed in the column during use, the capacitive sensing element comprising a planar, electrically-insulating substrate having first and second major surfaces with a pair of spaced-apart, parallel conductive strips on the first major surface and a continuous conductive sheet on the second major surface;
(c) a source of alternating current of a predetermined frequency coupled to one of the pair of parallel conductors; and
(d) a capacitance change circuit coupled to the other of the pair of parallel conductors.

2. The monitoring apparatus of claim 1 and further including a further conductive strip on the first major surface and located between the pair of parallel conductive strips where the further conductive strip and the continuous conductive sheet are connected to a source of reference potential.

3. The monitoring apparatus as in claim 2 and further including a coating of an anti-abrasive, non-conducting material on the first major surface overlaying the pair of conductive strips and the further conductive strip.

4. The monitoring apparatus as in claim 1 wherein the channel is formed of an electrically conductive metal.

5. The monitoring apparatus of claim 1 wherein the one side wall on which the capacitive sensing element is affixed has an edge portion bent out of the plane of the side wall in a direction to engage the capacitive sensing element along one edge of the substrate.

6. A monitoring apparatus for particulate material flowing through a conduit, comprising:
(a) a sampling chamber adapted to be disposed in a conduit through which particulate material is made to flow, the sampling chamber having an inlet end, an outlet end and at least one planar wall surface;
(b) a generally flat capacitive sensing element affixed to the planar wall and exposed to particulate material flowing through the sampling chamber, the capacitive sensing element comprising a planar electrically insulating substrate having first and second major surfaces with a pair of spaced-apart, parallel conductive strips on the first major surface and a continuous conductive sheet on the second major surface;
(c) a source of alternating current of a predetermined frequency coupled to one of the pair of parallel conductors; and
(d) means for measuring variations in capacitive reactance of the sensor due to changes in a property of the particulate material.

7. The moisture monitoring apparatus of claim 6 and further including a third conductive strip on the first major surface situated between the pair of conductive strips and where the third conductive strip and the conductive sheet are adapted to be connected to a source of reference potential.

8. The monitoring apparatus of claim 6 wherein the sampling chamber comprises a tubular body having an outward taper at the inlet end and an inward taper at the outlet end.

9. The monitoring apparatus of claim 7 and further including a protective dielectric layer covering the pair of conductive strips and the third conductive strip on the first major surface.

10. The monitoring apparatus of claim 9 wherein the capacitive sensing element is affixed with bolts to said planar wall.

11. The monitoring apparatus of claim 6 wherein the sampling chamber is made from a conductive material that serves to shield the sensing element from exposure to stray electric fields.

12. A method of monitoring the composition of particulate material while flowing through a conduit comprising the steps of:
(a) placing the sampling chamber of claim 6 within the conduit to intercept a substantially constant volume of a portion of the particular material flowing through the conduit; and
(b) sensing changes in the capacitance between the pair of conductive strips due to composition induced changes in the dielectric constant of the particulate material flowing through the conduit.

13. A method of monitoring the composition of particulate material while flowing through a conduit comprising the steps of:
(a) placing the sampling chamber of claim 7 within the conduit to intercept a substantially constant volume of a portion of the particular material flowing through the conduit; and
(b) sensing changes in the capacitance between the pair of conductive strips due to composition induced changes in the dielectric constant of the particulate material flowing through the conduit.

14. A method of monitoring the composition of particulate material while flowing through a conduit comprising the steps of:
(a) placing the sampling chamber of claim 8 within the conduit to intercept a substantially constant volume of a portion of the particular material flowing through the conduit; and
(b) sensing changes in the capacitance between the pair of conductive strips due to composition induced changes in the dielectric constant of the particulate material flowing through the conduit.

15. A method of monitoring the composition of particulate material while flowing through a conduit comprising the steps of:
(a) placing the sampling chamber of claim 9 within the conduit to intercept a substantially constant volume of a portion of the particular material flowing through the conduit; and
(b) sensing changes in the capacitance between the pair of conductive strips due to composition induced changes in the dielectric constant of the particulate material flowing through the conduit.

16. The method of monitoring as in any one of claims 12-15 wherein composition induced changes include changes in either particulate density or particulate moisture content.

17. The monitoring apparatus of any one of claims 6-11 wherein said property is one of particulate composition, particulate density and particulate moisture content.
